(19) United States
(12) Patent Application Publication
(10) Pub. No.: US 2007/0181338 A1
(43) Pub. Date: Aug. 9, 2007

(54) ASSEMBLED DEVICE AND SIGNAL FEEDING STRUCTURE THEREOF

(75) Inventor: Shu Chih Chen, Taipei County (TW)

Correspondence Address: QUINTERO LAW OFFICE, PC, 2210 MAIN STREET, SUITE 200, SANTA MONICA, CA, 90405, US

(73) Assignee: BENQ CORPORATION, TAOYUAN (TW)

(21) Appl. No.: 11/670,393

(22) Filed: Feb. 1, 2007

(30) Foreign Application Priority Data
Feb. 3, 2006 (TW) TW95103769

(51) Int. Cl. H05K 1/11; H01R 12/04

(52) U.S. Cl. 174/267

(57) ABSTRACT

A signal feeding structure of the invention includes a circuit board and a signal feeding component. The circuit board comprises a hole. The signal feeding component comprises a fixed portion electrically welded to the circuit board, a feeding portion extending from the fixed portion for feeding signal to the circuit board, and an extending portion extending from the fixed portion and welded in the hole of the circuit board. The fixed portion and the feeding portion forms an elastic structure.

### BACKGROUND OF THE INVENTION

1. Field of the Invention

The present invention relates to a signal feeding structure.

2. Description of the Related Art

In general, a signal feeding component is welded on a circuit board of a mobile phone by surface mounting (SMT) technology. Signal received by an antenna is fed into a circuit system of the mobile phone by the signal feeding component.

The signal feeding component, however, tends to be entangled by a passing object, such as a wire, causing it to disengage from the circuit board. Thus, a copper sheet formed on the circuit board is easily peeled and broken, resulting in malfunction of the circuit board.

### BRIEF SUMMARY OF THE INVENTION

A signal feeding structure of the invention comprises a circuit board and a signal feeding component. The circuit board comprises a hole. The signal feeding component comprises a fixed portion electrically welded to the circuit board, a feeding portion extending from the fixed portion for feeding signal to the circuit board, and an extending portion extending from the fixed portion and welded in the hole of the circuit board, wherein the fixed portion and the feeding portion forms an elastic structure, to thus reinforce the structure of the signal feeding structure and the circuit board, strengthening the bond between the signal feeding component and the circuit board, and to prevent a copper sheet formed on the circuit board from being peeled and destroying the circuit board when a force is abnormally applied thereon.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is an exploded view of a signal feeding structure (100) of a first embodiment of the invention;

FIG. 2 is an assembled view of the signal feeding structure (100) of the invention;

FIG. 3 is a side view of the assembled signal feeding structure (100) of the invention;

FIG. 4A is a perspective view of a signal feeding structure (5) of a second embodiment of the invention;

FIG. 4B is an exploded view of the signal feeding structure (5) of FIG. 4A;

FIG. 5A is an exploded view of an assembled device (K) of the invention; and

FIG. 5B is an assembled view of the assembled device (K) of FIG. 5A.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The invention provides a signal feeding component with a downward extending portion welded in a corresponding recess formed on a circuit board by pin through hole (PTH) technology, to reinforce the structure of the signal feeding structure and the circuit board.

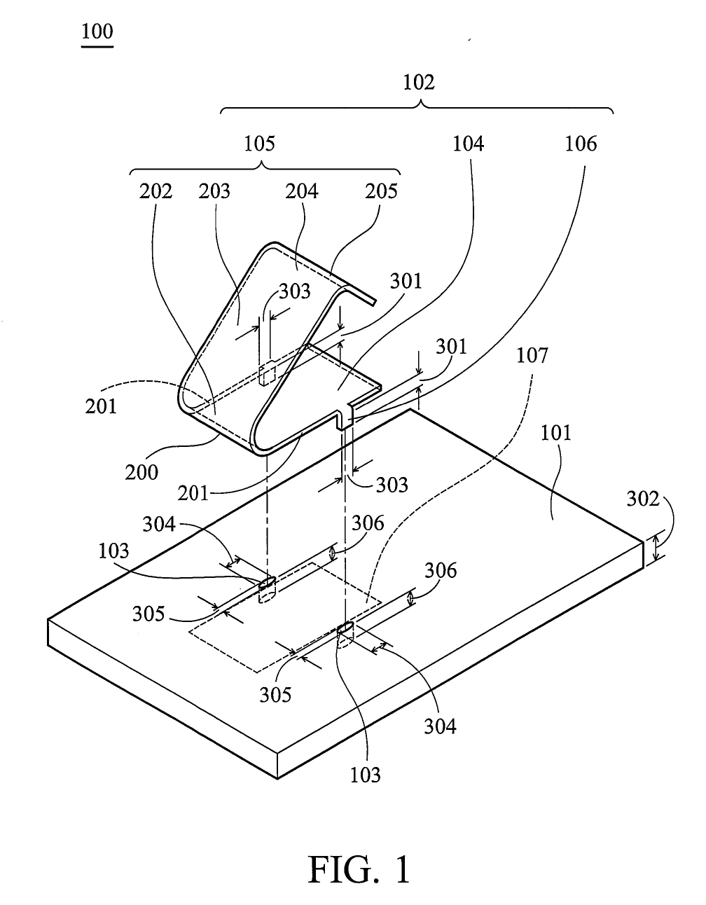

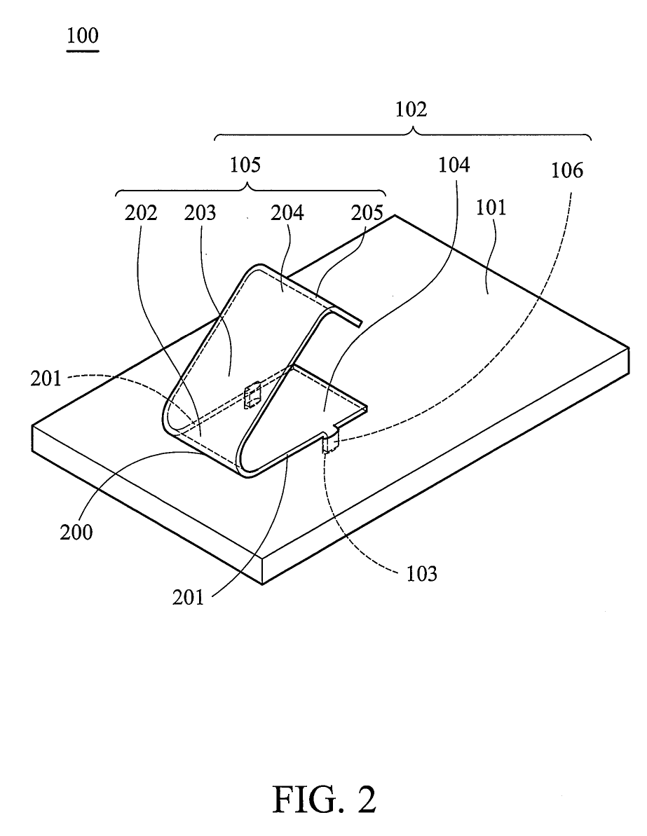

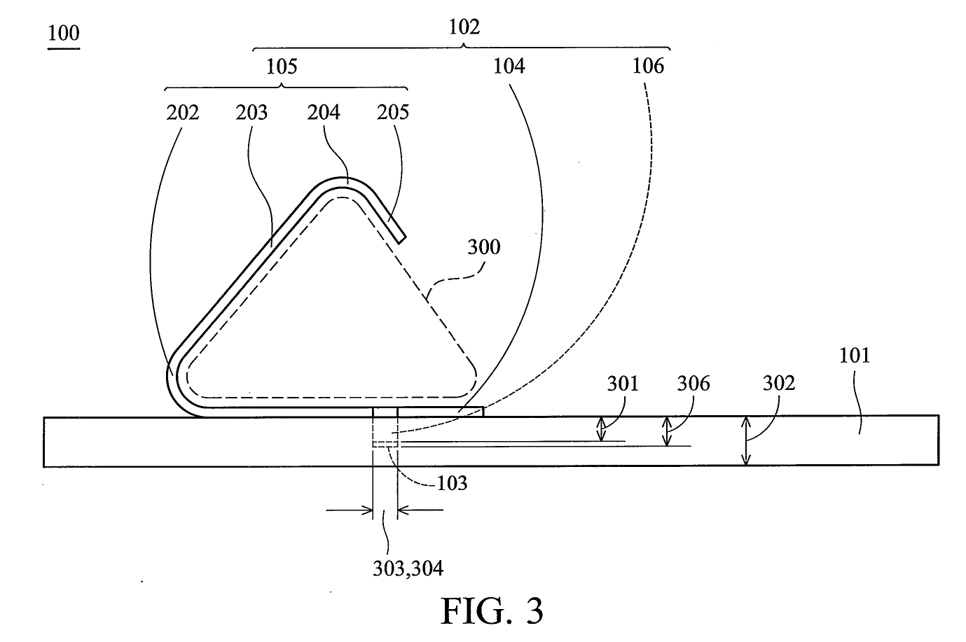

FIG. 1 is an exploded view of a signal feeding structure 100 of a first embodiment. FIG. 2 is an assembled view of the signal feeding structure 100 of FIG. 1. FIG. 3 is a side view of the assembled signal feeding structure 100 of FIG. 2.

The signal feeding structure 100 comprises a circuit board 101 and a signal feeding component 102. The circuit board 101 comprises two individual recesses 103 and a connecting surface 107. The signal feeding component 102 comprises a fixed portion 104, a feeding portion 105 and an extending portion 106. In this embodiment, the recess 103 is an elliptical recess or hole, and the fixed portion 104, the feeding portion 105 and the extending portion 106 are integrally formed by a metallic sheet. The fixed portion 104 and the feeding portion 105 form an elastic structure, e.g. a metallic spring leaf.

The substantially plate-like fixed portion 104 has a first edge 200 and two corresponding second edges 201. The feeding portion 105 substantially upwardly extends from the first edge 200 of the fixed portion 104. The fixed portion 104 is welded on the connecting surface 107 of the circuit board 101 by surface mounting SMT technology, so that the fixed portion 104 connected to the feeding portion 105 is electrically connected to the circuit board 101. Thus, an antenna signal from the feeding portion 105 can be fed into the circuit system of the circuit board 101.

The feeding portion 105 comprises a first curved portion 202 extending from the fixed portion 104, a first arm portion 203 extending from the first curved portion 202, a second curved portion 204 extending from the first arm portion 203 and a second arm portion 205 extending from the second curved portion 204. An angle is formed between the first curved portion 202 of the feeding portion 105 and the fixed portion 104.

In this embodiment, the feeding portion 105 is a bent metallic sheet. The first curved portion 202 substantially upwardly extends from the fixed portion 104, the first arm portion 203 upwardly and obliquely extends from the first curved portion 202, the second curved portion 204 extends downwardly from the first arm portion 203, and the second arm portion 205 extends downwardly and obliquely from the second curved portion 204.

A triangular open space 300 is substantially formed between the fixed portion 104 and the feeding portion 105, and a gap is formed between the second arm portion 205 and the fixed portion 104.

The extending portions 106 are two plate-like sheets, extending perpendicularly and downward from the second edges 201 of the fixed portion 104, i.e., the extending portions 106 are perpendicular to the fixed portion 104. In other embodiments, the extending portion 106 can be partially extended from the second edge 201. The longitude of the extending portion 106 is equal to or less than the thickness of the circuit board 101. The extending portions 106 are welded in the holes 103 of the circuit board 101 by pin through hole (PTH) technology, respectively.

In this embodiment, the feeding component 102 is integrally formed by a metallic sheet, having a dimension of 0.2-0.5 mm in thickness; the extending portion. 106 has a dimension 106 of 0.6-10 mm in length; the recess 103 has dimensions of 0.6-10 mm, 0.4-4 mm and 0.6-10 mm in length, width and depth, respectively; the extending portion 106 has a dimension of 0.4-4 mm in height; and the circuit board 101 has a dimension of 0.4-4 mm in thickness.

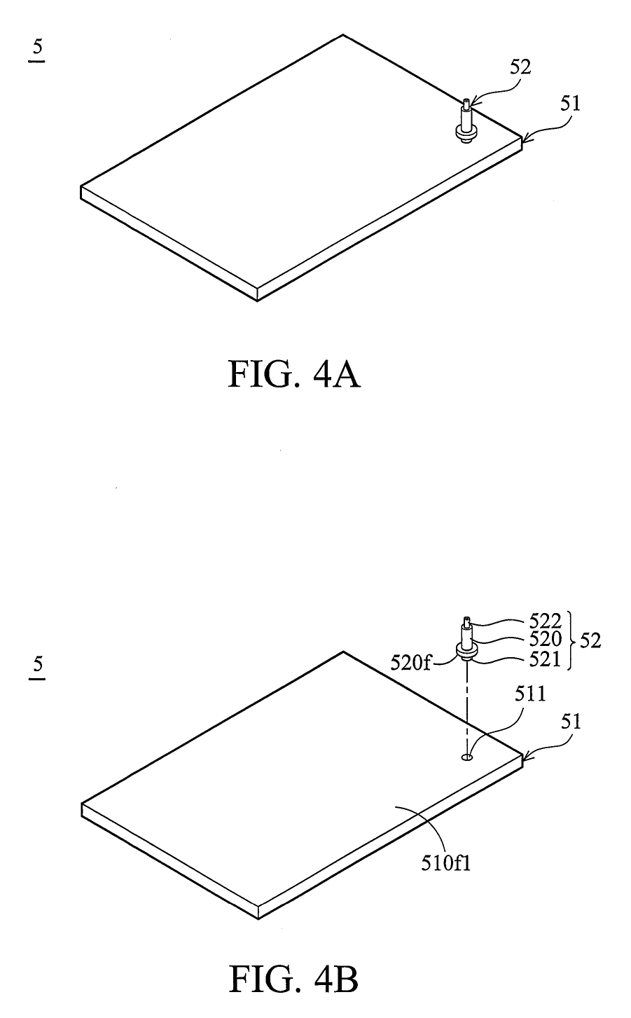

In FIGS. 4A and 4B, a signal feeding structure 5 of a second embodiment comprises a base plate 51 and a signal feeding component 52. The base plate 51 comprises a base surface 510f1 and a first positioning portion 511 disposed on the base surface 510f1. In this embodiment, the base plate 51 is a circuit board, and the first positioning portion 511 is a through hole formed on the base surface 510f1. In other embodiments, the first positioning portion 511 can be a blind hole.

The signal feeding component 52 comprises a cylindrical body 520 having a connecting surface 520f, a second positioning portion 521 protruded from the connecting surface 520f, and a contact portion 522 retractably disposed on the body 520.

When the connecting surface 520f of the signal feeding component 52 is connected to the base surface 510f1 of the base plate 51, the second positioning portion 521 of the signal feeding component 52 is positioned in the first positioning portion 511 of the base plate 51.

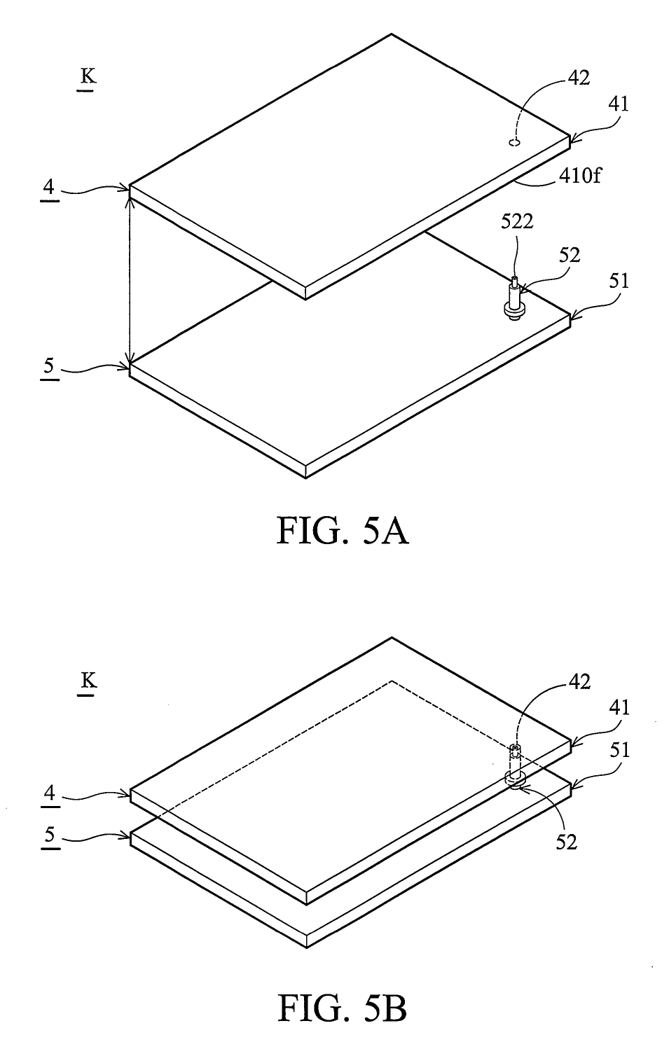

In FIG. 5A, an assembled device K comprises a predetermined structure 4 and the signal feeding structure 5. The predetermined structure 4 comprises a contact pad 42. The signal feeding component 52 of the signal feeding structure 5 detachably contacts the contact pad 42 of the predetermined structure 4, thus the signal feeding structure 5 is electronically connected to the predetermined structure 4. When the connecting surface 520f of the signal feeding component 52 is connected to the base surface 510f1 of the base plate 51, the second positioning portion 521 of the signal feeding component 52 is positioned in the first positioning portion 511 of the base plate 51. In this embodiment, the predetermined structure 4 is a circuit board.

In FIG. 5B, when the contact portion 522 of the signal feeding component 52 contacts the contact pad 42 of the predetermined structure 4, the predetermined structure 4 and the signal feeding structure 5 are electrically connected.

The signal feeding component provides the downward extending portions welded in the corresponding recesses formed on a circuit board by pin through hole (PTH) technology, to reinforce the structure of the signal feeding structure and the circuit board, strengthening the bond between the signal feeding component and the circuit board, and to prevent a copper sheet formed on the circuit board from being peeled and destroying the circuit board when a force is abnormally applied thereon.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A signal feeding structure, comprising:
a circuit board comprising a hole; and
a signal feeding component comprising a fixed portion electrically welded to the circuit board, a feeding portion extending from the fixed portion for feeding signal to the circuit board, and an extending portion extending from the fixed portion and welded in the hole of the circuit board, wherein the fixed portion and the feeding portion forms an elastic structure.

2. The signal feeding structure as claimed in claim 1, wherein the fixed portion is disposed on the circuit board by surface mounting technology.

3. The signal feeding structure as claimed in claim 1, wherein the extending portion is welded in the hole of the circuit board by pin through hole technology.

4. The signal feeding structure as claimed in claim 1, wherein the longitude of the extending portion is equal to or less than the thickness of the circuit board.

5. The signal feeding structure as claimed in claim 1, wherein the shape of the fixed portion is substantially plate-like.

6. The signal feeding structure as claimed in claim 1, wherein the hole of the circuit board comprises an elliptical recess.

7. The signal feeding structure as claimed in claim 1, wherein the signal comprises an antenna signal.

8. The signal feeding structure as claimed in claim 1, wherein the feeding portion comprises a bent metallic sheet, and an angle is formed between the feeding portion and the fixed portion.

9. The signal feeding structure as claimed in claim 1, wherein the shape of the extending portion is substantially plate-like and perpendicular to the fixed portion.

10. The signal feeding structure as claimed in claim 1, wherein the fixed portion comprises a first edge and a second edge, wherein the feeding portion extends from the first edge and the extending portion extends from the second edge.

11. The signal feeding structure as claimed in claim 10, wherein the extending portion partially extends from the second edge.

12. The signal feeding structure as claimed in claim 1, wherein the feeding portion substantially upwardly extends from the fixed portion, and the extending portion substantially downwardly extends from the fixed portion.

13. The signal feeding structure as claimed in claim 1, wherein the fixed portion, the feeding portion and the extending portion are integrally formed.

14. The signal feeding structure as claimed in claim 1, wherein the fixed portion and the feeding portion are integrally formed into a metallic spring leaf.

15. The signal feeding structure as claimed in claim 1, wherein the circuit board comprises two individual holes, the fixed portion comprises two corresponding edges, and the extending portion comprises two individual metallic sheets, wherein the metallic sheets of the extending portion respectively extending from the edges of the fixed portion are respectively welded in the holes of the circuit board.

16. The signal feeding structure as claimed in claim 1, wherein the feeding portion comprises a first curved portion extending from the fixed portion, a first arm portion extending from the first curved portion, a second curved portion extending from the first arm portion and a second arm portion extending from the second curved portion.

17. The signal feeding structure as claimed in claim 16 further comprising a triangular open space substantially formed between the fixed portion and the feeding portion.

18. The signal feeding structure as claimed in claim 16, wherein the first curved portion substantially upwardly extends from the fixed portion, the first arm portion substantially upwardly and obliquely extends from the first curved portion, the second curved portion substantially downwardly extends from the first arm portion, and the second arm portion substantially downwardly and obliquely extends from the second curved portion.

19. The signal feeding structure as claimed in claim 18, wherein the first arm portion substantially perpendicularly extends away from the fixed portion and horizontally approaches to the fixed portion to obliquely and upwardly extend, and the second arm portion substantially approaches to the fixed portion to be obliquely and downwardly extended.

20. The signal feeding structure as claimed in claim 16, wherein the first and second curved portions and comprise metallic curved sheets and, and the first and second arm portions and comprise metallic plate sheets and.

21. A signal feeding structure, comprising:
a base plate comprising a base surface and a first positioning portion disposed on the base surface; and
a signal feeding component comprising a connecting surface and a second positioning portion, wherein the second positioning portion of the signal feeding component is positioned in the first positioning portion of the base plate when the connecting surface of the signal feeding component is connected to the base surface of the base plate.

22. The signal feeding structure as claimed in claim 21, wherein the first positioning portion comprises a hole formed on the base surface of the base plate.

23. The signal feeding structure as claimed in claim 21, wherein the second positioning portion comprises a protrusion formed on the connecting surface of the signal feeding component.

24. The signal feeding structure as claimed in claim 21, wherein the signal feeding component is disposed on the base plate by surface mounting technology.

25. The signal feeding structure as claimed in claim 21, wherein the base plate comprises a circuit board.

26. An assembled device, comprising:
a predetermined structure comprising a contact pad; and
a signal feeding structure electronically connected to the predetermined structure, comprising a base plate and a signal feeding component detachably contacting the contact pad of the predetermined structure, wherein the base plate comprises a base surface and a first positioning portion disposed on the base surface, and the signal feeding component comprises a connecting surface and a second positioning portion, wherein the second positioning portion of the signal feeding component is positioned in the first positioning portion of the base plate when the connecting surface of the signal feeding component is connected to the base surface of the base plate.
